(19) United States
(12) Patent Application Publication
(10) Pub. No.: US 2002/0003311 A1
(43) Pub. Date: Jan. 10, 2002

(54) SEMICONDUCTOR DEVICE WITH HIGH RESISTANCE ELEMENT AND PROCESS FOR MANUFACTURING THE SAME

(76) Inventor: YOSHIHIDE UEMATSU, TOKYO (JP)

Correspondence Address: SUGHRUE MION ZINN MACPEAK & SEAS, 2100 PENNSYLVANIA AVENUE N W, WASHINGTON, DC, 20037

(21) Appl. No.: 09/093,932

(22) Filed: Jun. 9, 1998

(30) Foreign Application Priority Data
Jun. 9, 1997 (JP) 9-151110

(51) Int. Cl. H01L 27/11

(52) U.S. Cl. 257/903; 257/904

(57) ABSTRACT

A high resistance element which is a loading resistor of a SRAM is produced from a high resistance film composed of a SIPOS film in such a manner that the high resistance film is in contact with a junction region formed of a low resistance polysilicon film. This structure ensures that the resistance of a joint portion of the high resistance element of a semiconductor device can be reduced.

### BACKGROUND OF THE INVENTION

1. Field of the Invention

This invention relates to a semiconductor device provided with a high resistance element and a process for manufacturing the semiconductor device.

2. Description of the Related Art

An SRAM semiconductor memory device is a typical semiconductor device provided with a high resistance element. The SRAM semiconductor memory device, as shown in FIG. 1, has many memory cells (SRAM cells) including a flip-flop circuit. This flip-flop circuit comprises a first inverter having a first loading resistor R1 consisting of a first insulating gate transistor T1 and a first high resistance element and a second inverter having a second loading resistor R2 consisting of a second insulating gate transistor T2 and a second high resistance element. Output signals from the first and second inverters are applied to the gate electrode of the second insulating gate transistor T2 and the gate electrode of the first insulating gate transistor T1 respectively. In FIG. 1, a Wi1 and a Wi2 are word conductors, a VDi1 and a VDi2 are power source conductors, a GND is a grounding conductor, and a Di is a bit conductor. A Di with an over line mark shows a reverse signal conductor of the bit conductor.

A SRAM using a SIPOS (Semi Insulated Poly-Silicon) film as the loading resistors R1 and R2 is disclosed in Japanese Patent Application Laid-Open (JP-A) No. 3-165553.

The steps of a process for producing such a conventional SRAM semiconductor device will be explained in sequence. A fist step is illustrated in a top plan view of FIG. 2 and a sectional view of FIG. 3. In FIG. 2, a part enclosed by the two-dot chain lines A, B, C, and D indicates one SRAM cell, which is the same as in the following Figures. FIG. 3 is a sectional view along the line Y-Y in FIG. 2. First, element isolation regions (field oxide film 2) are formed in the surface portion of a p-type silicon semiconductor as the partitions to form a first active region 3-1 and a second active region 3-2. Next, a gate oxide film 4 is formed on the surfaces of the first active region 3-1 and second active region 3-2.

A second step is illustrated in a top plan view of FIG. 4 and a sectional view of FIG. 5. FIG. 5 is a sectional view along the line Y-Y in FIG. 4. As shown in FIGS. 4 and 5, a polysilicon film 5 doped with phosphorus is formed. The polysilicon film 5 is patterned to form a first gate electrode 5(g1) crossing over the first active region 3-1 and extending to the periphery of the second active region 3-2; a second gate electrode 5 (g2) crossing over the second active region 3-2 and extending to the periphery of the first active region 3-1; a third gate electrode 5 (g3) crossing over the first active region 3-1 whose periphery is selectively coated with the second gate electrode 5 (g2) and serving as the first word conductor Wi1; and a fourth gate electrode 5 (g4) crossing over the second active region 3-2 whose periphery is selectively coated with the first gate electrode 5 (g1) and serving as the second word conductor Wi2. The same signal as that applied to the word conductor Wi1 is applied to the second word conductor Wi2.

Using, as a mask, the first gate electrode 5 (g1) to the fourth gate electrode 5 (g4) and the element isolation region 2, an impurity (phosphorus) is introduced into the first active region 3-1 and the second active region 3-2 to form a plurality of n+-type regions 6-1, 6-2, 6-13, and 6-24. A first insulating gate transistor T1 to a fourth insulating gate transistor T4 which are provided with the first gate electrode 5 (g1) to the fourth gate electrode 5 (g4) respectively are thus formed.

A third step is illustrated in a top plan view of FIG. 6 and a sectional view of FIG. 7. FIG. 7 is a sectional view along the line Y-Y in FIG. 6. As shown in FIGS. 6 and 7, a first layer insulating film 7 (silicon oxide film) is deposited to form a first earth contact hole C1-1 and a second earth contact hole C1-2 on a source region of the first insulating gate transistor T1 as the n+ region 6-1 which is not sandwiched between the first gate electrode 5 (g1) and the third gate electrode 5 (g3) and on a source region of the second insulating gate transistor T2 as the n+-type region 6-2 which is not sandwiched between the second gate electrode 5 (g2) and the fourth gate electrode 5 (g4) respectively.

In succession, an electro-conductive film 8 such as a tungsten silicide film is deposited. The patterning of the film 8 is performed to form an earth wiring layer 8 (GND).

A fourth step is illustrated in a top plan view of FIG. 8 and a sectional view of FIG. 9. FIG. 9 is a sectional view along the line Y-Y in FIG. 8. As shown in FIGS. 8 and 9, a second layer insulating film 9 is deposited. Then, a first common contact hole C2-1 and a second common contact hole C2-2 are formed. The first common contact hole C2-1 is an n+-type region 6-13 sandwiched between the first gate electrode 5 (g1) and the third gate electrode 5 (g3) and exposes a drain region of the first insulating gate transistor T1 and the second gate electrode 5 (g2) adjacent to the drain region. The second common contact hole C2-2 is an n+-type region 6-24 sandwiched between the second gate electrode 5 (g2) and the fourth gate electrode 5 (g4) and exposes a drain region of the second insulating gate transistor T2 and the first gate electrode 5 (g1) adjacent to the drain region.

Next, a SIPOS film 10 is formed as a high resistance film. An oxygen atom is introduced into a polysilicon film by a CVD method making use of a reaction of a mixture gas of SiH₄ and N₂O to form the SIPOS film 10 as described in Japanese Patent Application Laid-Open (JP-A) No. 3-165553.

After the SIPOS film 10 is patterned, it is doped with phosphorus ions with a dose of 5×10¹⁵ to 5×10¹⁷ cm⁻², typically about 1×10¹⁶ cm⁻², using a resist film (not shown) as a mask. Then, the resist film is removed and the substrate is annealed at 1,000 to 1,200° C. by lamp heating for a time as short as about 3 seconds.

In this manner, a loading resistor R1 is obtained which consists of the high resistance SIPOS film 10 (R1), a common contact 10-1 (R1) formed of a low resistance SIPOS film which is connected to one side of the high resistance SIPOS film 10 (R1), and a power source wiring section 10-2 (Vdi1) connected to the other side of the high resistance SIPOS film 10 (R1). Similarly a loading resistor R2 is obtained which consists of the high resistance SIPOS film 10 (R2), a common contact 10-1 (R2) formed of a low resistance SIPOS film which is connected to one side of the high resistance SIPOS film 10 (R2), and a power source wiring section 10-2 (Vdi2) connected to the other side of the high resistance SIPOS film 10 (R2). The same voltages are applied to the power source wiring sections VDi1 and VDi2.

A fifth step is illustrated in a top plan view of FIG. 10 and a sectional view of FIG. 11. FIG. 11 is a sectional view along the line Y-Y in FIG. 10. As shown in FIGS. 10 and 11, a layer insulating film 11 is deposited, bit contact holes C3-1 and C3-2 extending to n+-type diffusion layers 6-3 and 6-4 respectively are then formed, and bit conductors 12 (Di) and 12 (Ndi) are finally formed.

In this method for producing the conventional high resistance element, an impurity such as phosphorus is introduced into the SIPOS film to form junctions (common contact and power source wiring section), thereby giving rise to the following problem. FIG. 12 is a graph shown as FIG. 2 in the aforementioned Japanese Patent Application Laid-Open (JP-A) No. 3-165553, which graph shows the relation of sheet resistance of a SIPOS film vs dose amount of ion. As shown in FIG. 12, an implantation of phosphorus ions enables it possible to reduce the sheet resistance to as low as about 480Ω/□.

When the depths of junctions of the n+-type regions 6-1, 6-4, and the like are made shallow with a reduction in size and increase in speed of the SRAM, strict limitations on acceleration voltage and annealing conditions are made. This causes easy production of a high resistance section 10-C with a low phosphorus concentration as shown in FIG. 9. The concentration dependency of the sheet resistance is relatively steep and hence the resistance of the common contact varies. Also, such a resistance as 480Ω/□ is not yet low for a power source wire. Because of this, the stable action of the SRAM is impaired. As is clear from the above explanations, the SIPOS film is featured in that a resistance as high as several to tens of TΩ/□ is realized, but on the other hand the resistance of the junction can be reduced only with difficulty.

### SUMMARY OF THE INVENTION

It is an object of the present invention to provide a semiconductor device mounted with a high resistance element ensuring that the resistance of the junction can be further reduced and a process for manufacturing the semiconductor device.

According to a first aspect of the present invention, there is provided a semiconductor device mounted with a high resistance element comprising:

a pair of junction regions formed of a low resistance polysilicon film, the pair of junction regions being formed on a semiconductor substrate; and

a high resistance film which is in contact with the pair of junction regions.

In the invention, the high resistance film may be a SIPOS film formed of a silicon film containing oxygen.

According to another aspect of the present invention, there is provided a semiconductor device comprising:

a first inverter provided with a first loading resistor consisting of a first insulating gate transistor and a first high resistance element;

a second inverter provided with a second loading resistor consisting of a second insulating gate transistor and a second high resistance element; and

a memory cell containing a flip-flop circuit which applies output signals from the first and second inverters to gate electrodes of the second and first insulating gate transistors respectively.

Said first high resistance element consists of a first low resistance polysilicon film connected with a drain region of the first insulating gate transistor, a second low resistance polysilicon film to which a prescribed voltage is applied, and a first high resistance film which is in contact with the first low resistance polysilicon film and the second low resistance polysilicon film.

Said second high resistance element consists of a third low resistance polysilicon film connected with a drain region of the second insulating gate transistor, a fourth low resistance polysilicon film to which a prescribed voltage is applied, and a second high resistance film which is in contact with the third low resistance polysilicon film and the fourth low resistance polysilicon film.

In the invention, each of the first and second high resistance films may be a SIPOS film formed of a silicon film containing oxygen.

According to a further aspect of the present invention, there is provided a process for manufacturing a semiconductor device comprising the steps of:

forming a low resistance silicon film doped with an impurity on a semiconductor substrate;

patterning the low resistance silicon film to form a pair of junction regions;

forming a high resistance film which is in contact with the pair of junction regions; and

patterning the high resistance film to form a high resistance element.

In the invention, as the high resistance film, a SIPOS film composed of a silicon film containing oxygen may be formed by a CVD method in an atmosphere involving SiH4 gas and N2O gas.

According to a still further aspect of the present invention, there is provided a process for manufacturing a semiconductor device comprising the steps of:

forming an element isolation region in the surface of a first electro-conductive region disposed in the surface section of a semiconductor substrate to form partitioned first and second active regions;

forming a gate insulating film on the first and second active regions;

forming a polysilicon film doped with a second electro-conductive-type impurity;

patterning said polysilicon film to form a first gate electrode crossing over the first active region and extending to the periphery of the second active region; a second gate electrode crossing over the second active region and extending to the periphery of the first active region; a third gate electrode crossing over the first active region whose periphery is selectively coated with the second gate electrode and serving as the first word conductor; and a fourth gate electrode crossing over the second active region whose periphery is selectively coated with the first gate electrode and serving as the second word conductor;

introducing an impurity into the first and second active regions using, as a mask, the first gate electrode to the fourth gate electrode and the element isolation region to form a plurality of second electro-conductive-type regions thereby creating a first insulating gate transistor to a fourth insulating gate transistor which are provided with the first gate electrode to the fourth gate electrode respectively;

depositing a first layer insulating film to form a first earth contact hole and a second earth contact hole on a source region of the first insulating gate transistor as the second electro-conductive-type region which is not sandwiched between the first gate electrode and the third gate electrode and on a source region of the second insulating gate transistor as the second electro-conductive-type region which is not sandwiched between the second gate electrode and the fourth gate electrode respectively;

depositing an electro-conductive film, followed by patterning to form an earth wiring layer;

depositing a second layer insulating film to form a first common contact hole and a second common contact hole, the first common contact hole exposing a drain region of the first insulating gate transistor as the second electro-conductive-type region which is sandwiched between the first and third gate electrodes and the second gate electrode adjacent to the drain region, and the second common contact hole exposing a drain region of the second insulating gate transistor as the second electro-conductive-type region which is sandwiched between the second and fourth gate electrodes and the first gate electrode adjacent to the drain region;

forming a polysilicon film doped with a second electro-conductive-type impurity, followed by patterning to form a first junction region and a second junction region and a first power source wiring layer and a second power source wiring layer for filling up the first and second contact holes; and successively forming a first high resistance film connected with the first junction region and the first power source wiring layer and a second high resistance film connected with the second junction region and the second power source wiring layer; and

depositing a third layer insulating film to form a first bit contact hole and a second bit contact hole for exposing the second electro-conductive-type region formed sandwiching the third gate electrode between the drain region of the first insulating gate transistor and the second electro-conductive-type region formed sandwiching the fourth gate electrode between the drain region of the second insulating gate transistor; and successively forming a first bit wiring layer and a second bit wiring layer for filling up the first and second bit contact holes respectively to form a memory cell.

In the invention, a SIPOS film composed of a silicon film containing oxygen may be formed by a CVD method in an atmosphere involving SiH4 gas and N2O gas, followed by patterning, to form the first and second high resistance films.

Because a pair of junction regions is formed in such a manner that it is in contact with a high resistance film in this invention, the resistance of the junctions of a high resistance element can be reduced.

### BRIEF DESCRIPTION OF THE DRAWINGS

FIG. 1 is a circuit diagram of a SRAM cell;

FIG. 2 is a top plan view illustrating a first step in a process for manufacturing a conventional SRAM;

FIG. 3 is a sectional view along the line Y-Y in FIG. 2;

FIG. 4 is a top plan view illustrating a second step in the process for manufacturing the conventional SRAM;

FIG. 5 is a sectional view along the line Y-Y in FIG. 4;

FIG. 6 is a top plan view illustrating a third step in the process for manufacturing the conventional SRAM;

FIG. 7 is a sectional view along the line Y-Y in FIG. 6;

FIG. 8 is a top plan view illustrating a fourth step in the process for manufacturing the conventional SRAM;

FIG. 9 is a sectional view along the line Y-Y in FIG. 8;

FIG. 10 is a top plan view illustrating a fifth step in the process for manufacturing the conventional SRAM;

FIG. 11 is a sectional view along the line Y-Y in FIG. 10;

FIG. 12 is a graph shows the relationship of layer resistance of SIPOS film and dose amount of ion;

FIG. 13 is a top plan view showing a SRAM of an embodiment according to the present invention;

FIG. 14 is a sectional view along the line Y-Y in FIG. 13;

FIG. 15 is a top plan view illustrating one primary process in a process for manufacturing the SRAM of the embodiment according to the present invention;

FIG. 16 is a sectional view along the line Y-Y in FIG. 15;

FIG. 17 is a top plan view illustrating a step following the step of FIG. 15; and

FIG. 18 is a sectional view along the line Y-Y in FIG. 17.

### DESCRIPTION OF THE PREFERRED EMBODIMENT

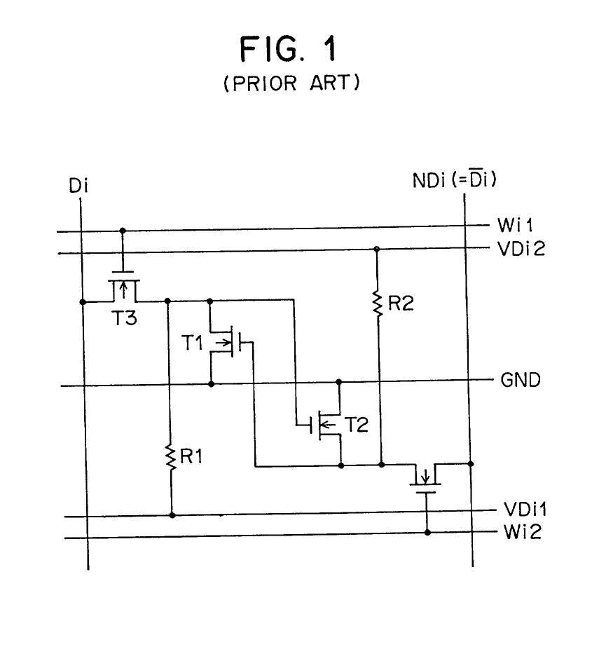

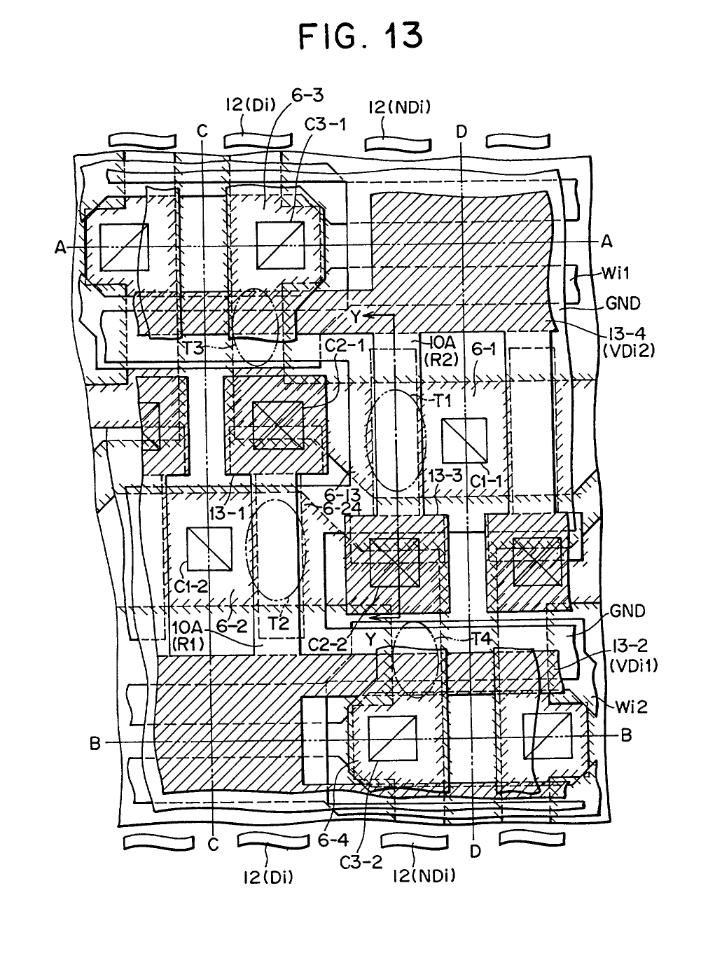

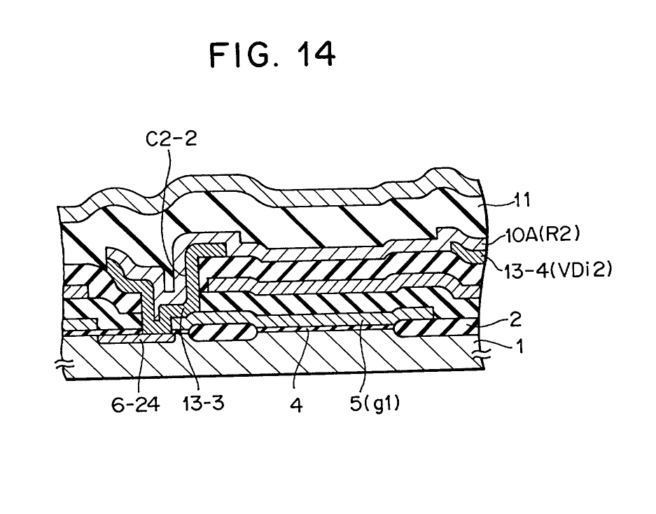

FIG. 13 is a top plan view showing a semiconductor memory device (SRAM) provided with a high resistance element corresponding to an embodiment of the present invention and FIG. 14 is an enlarged sectional view along the line Y-Y in FIG. 13. It is noted that the circuit diagram of the semiconductor memory device is similar to that of FIG. 1.

In this embodiment, a first inverter comprises a first loading resistor R1 consisting of a first insulating gate transistor T1 and a first high resistance element and a second inverter comprises a second loading resistor R2 consisting of a second insulating gate transistor T2 and a second high resistance element. Output signals from the first and second inverters are applied to a gate electrode of the second insulating gate transistor T2 and a gate electrode of the first insulating gate transistor T1 respectively. In this manner, a memory cell (SRAM cell) comprises a flip-flop circuit constituted of the first and second inverters.

In this embodiment, a first high resistance element R1 comprises a first low resistance polysilicon film 13-1 connected to a drain region 6-13 of the first insulating gate transistor T1, a second low resistance polysilicon film 13-2 (VDi1) to which a prescribed voltage is applied, and a first high resistance film 10A (R1) which is in contact with the first low resistance polysilicon film 13-1 and the second low resistance polysilicon film 13-2 (VDi1). A second high resistance element R2 comprises a third low resistance polysilicon film 13-3 connected to a drain region 6-24 of the second insulating gate transistor T2, a fourth low resistance polysilicon film 13-4 (VDi2) to which a prescribed voltage is applied, and a second high resistance film 10A (R2) which is in contact with the third low resistance polysilicon film 13-3 and the fourth low resistance polysilicon film 13-4 (VDi2).

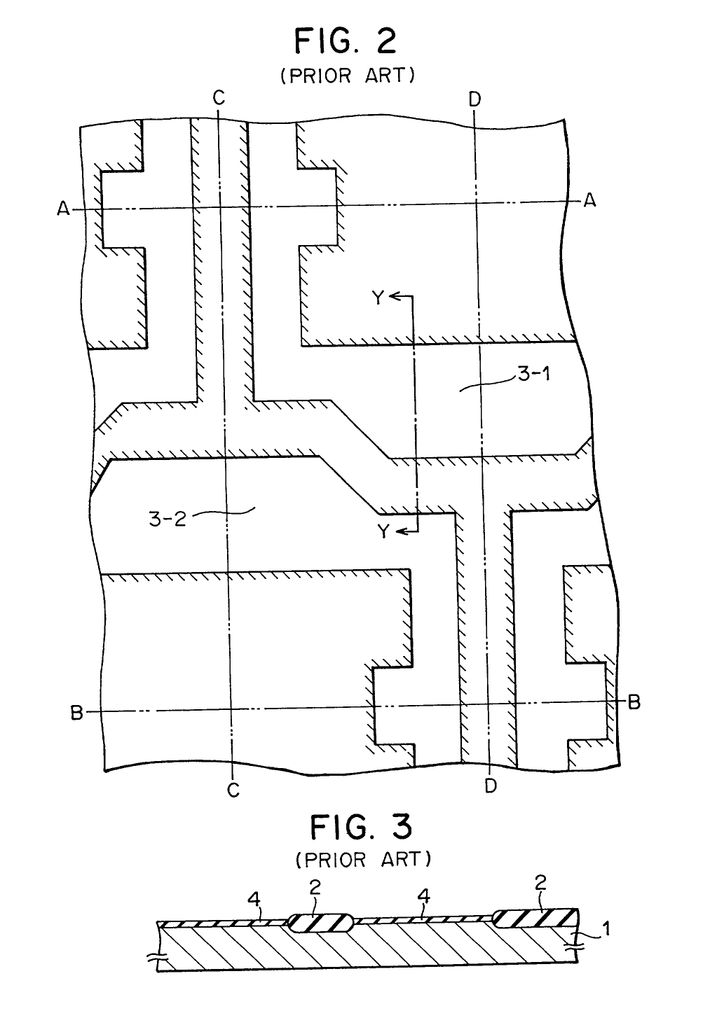

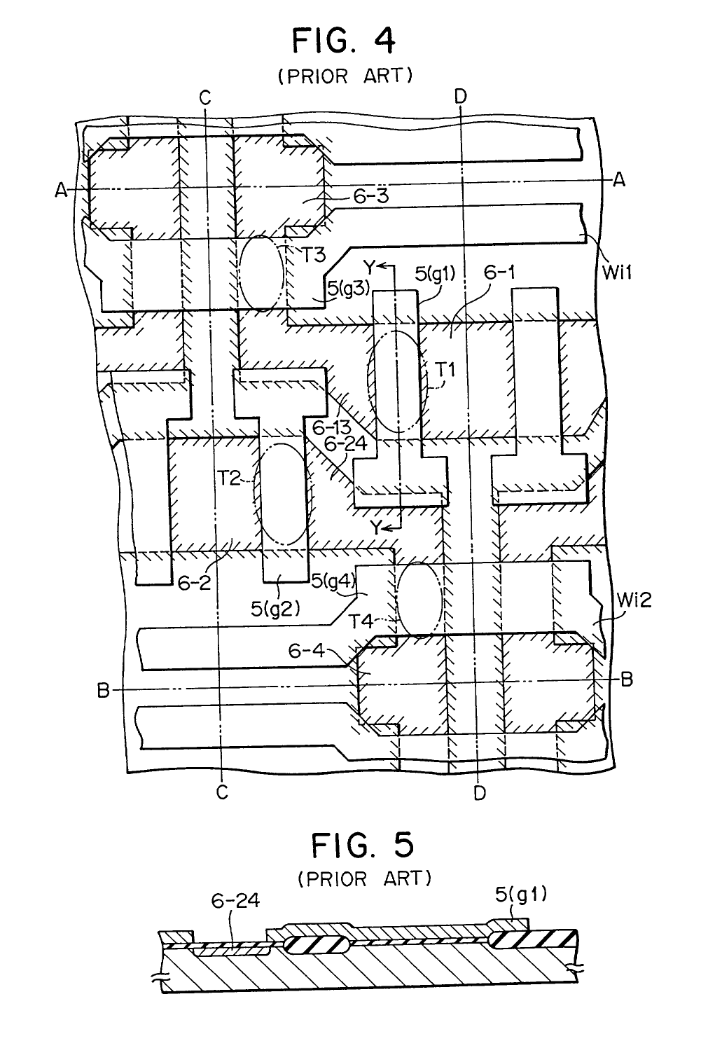

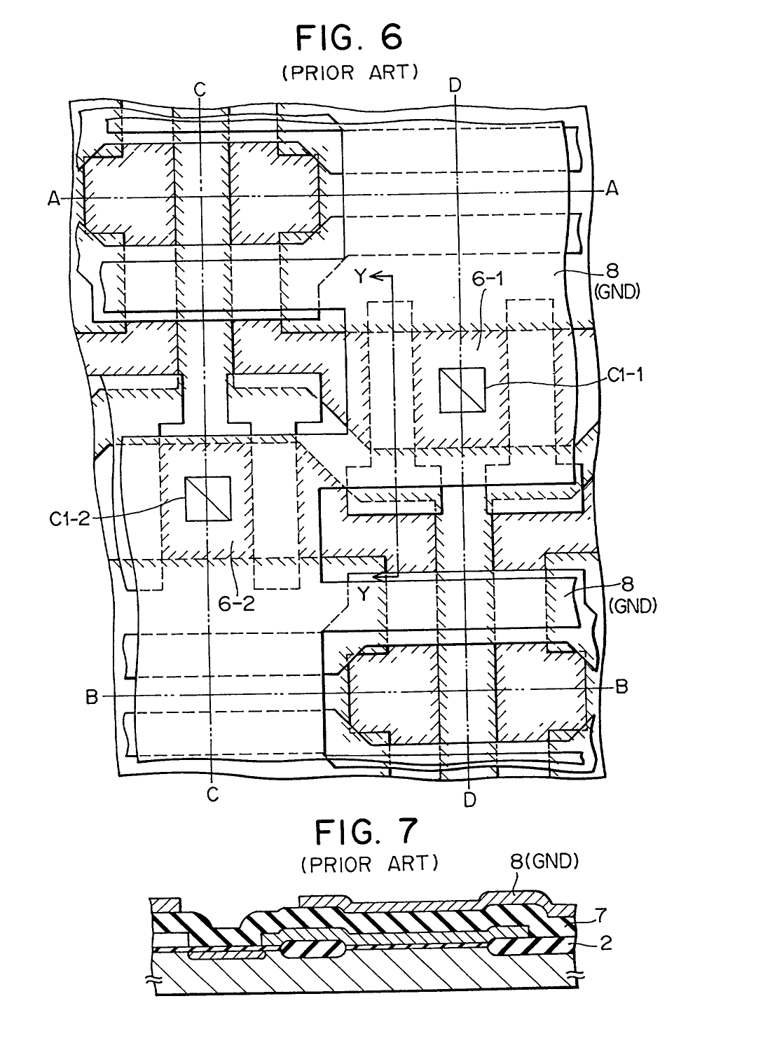

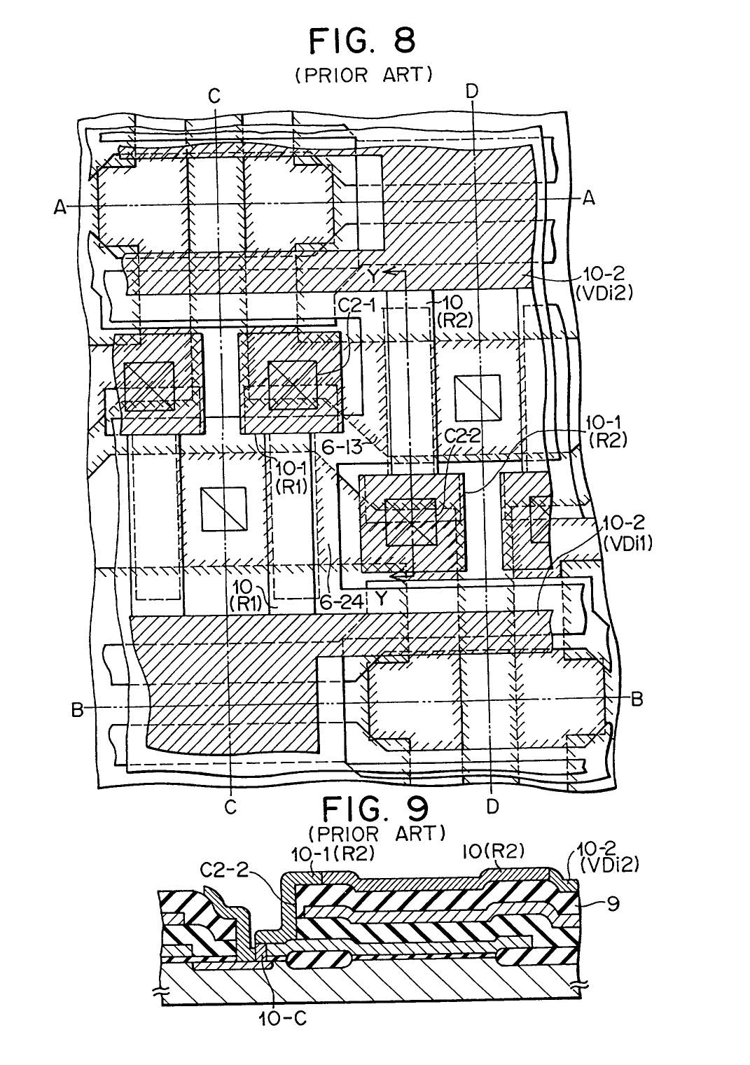

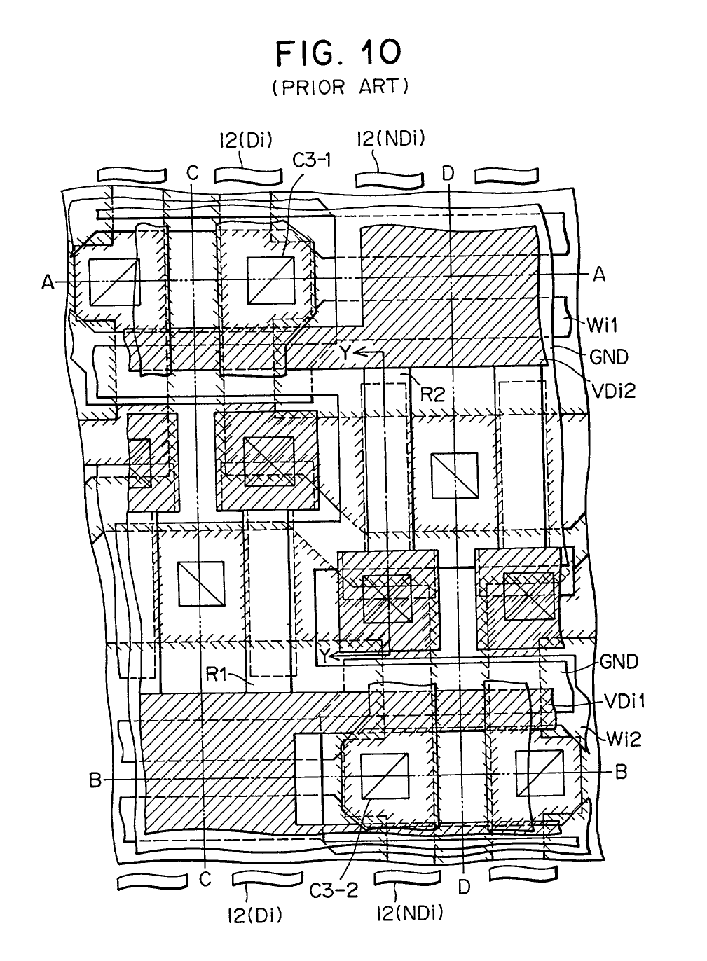

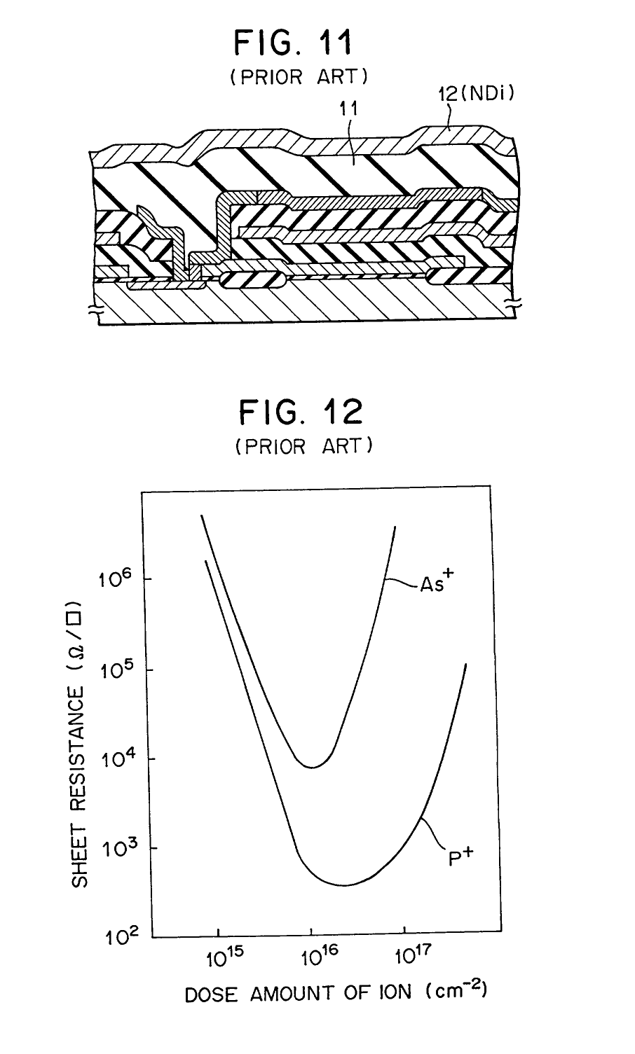

Next, a process for manufacturing the SRAM is now explained. First, the same steps as the conventional steps 1 to 4 as shown in FIGS. 2 to 9 are carried out to produce common contact holes C2-1 and C2-2. In other words, only steps preceding the conventional step of forming the SIPOS film 10 as the high resistance film are carried out in these steps. Therefore, repetitive explanations about the steps of forming the common contact holes C2-1 and C2-2 are omitted.

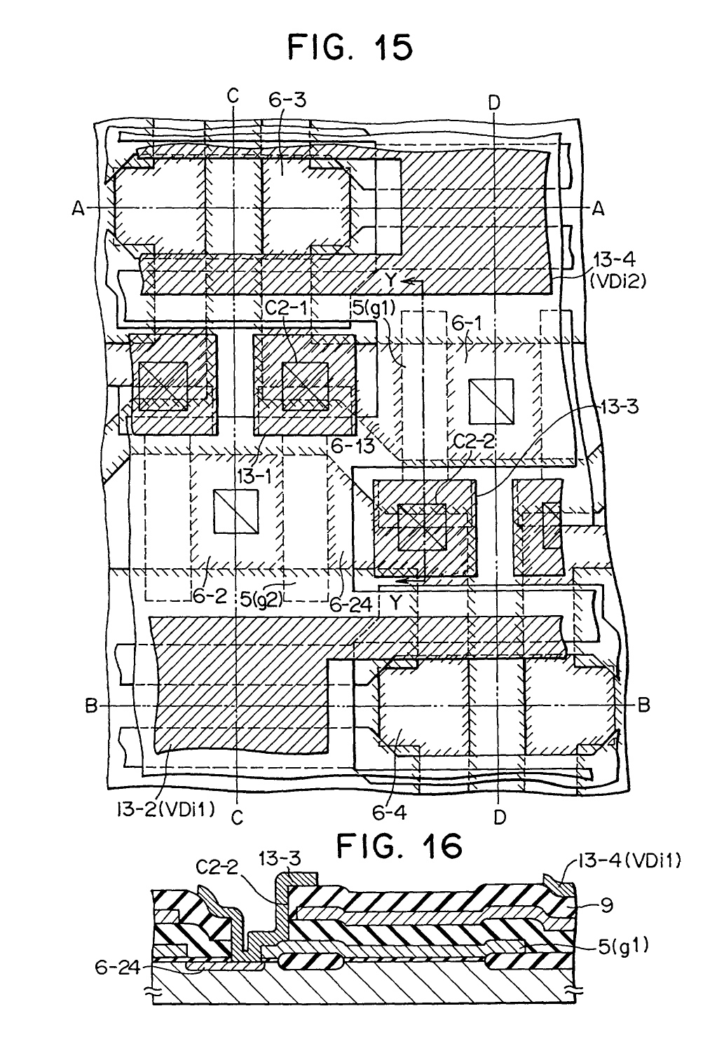

The next step will be illustrated with reference to FIG. 15 and FIG. 16 which is a sectional view along the line Y-Y in FIG. 15. As shown in FIGS. 15 and 16, a low resistance polysilicon film 13 is formed with the entire surface thereof being doped with phosphorus, followed by patterning to form a first junction region 13-1, a second junction region 13-3, a first power source wiring layer 13-2 (VDi1), and a second power source layer 13-4 (VDi2), the layer resistance of these being all tens of Ω/□. The first junction region 13-1 covers the first contact hole C2-1 and is in contact with an n+-type region 6-13 and a gate electrode 5 (g2). The second junction region 13-3 covers the second contact hole C2-2 and is in contact with an n+-type region 6-24 and a gate electrode 5 (g1).

Next, a SIPOS film 10A is formed by a CVD method using reacting gas consisting of SiH4 gas and N2O gas. This method enables it possible to form a high resistance film composed of a silicon grain and a grain boundary of SiOx (0<x≦2).

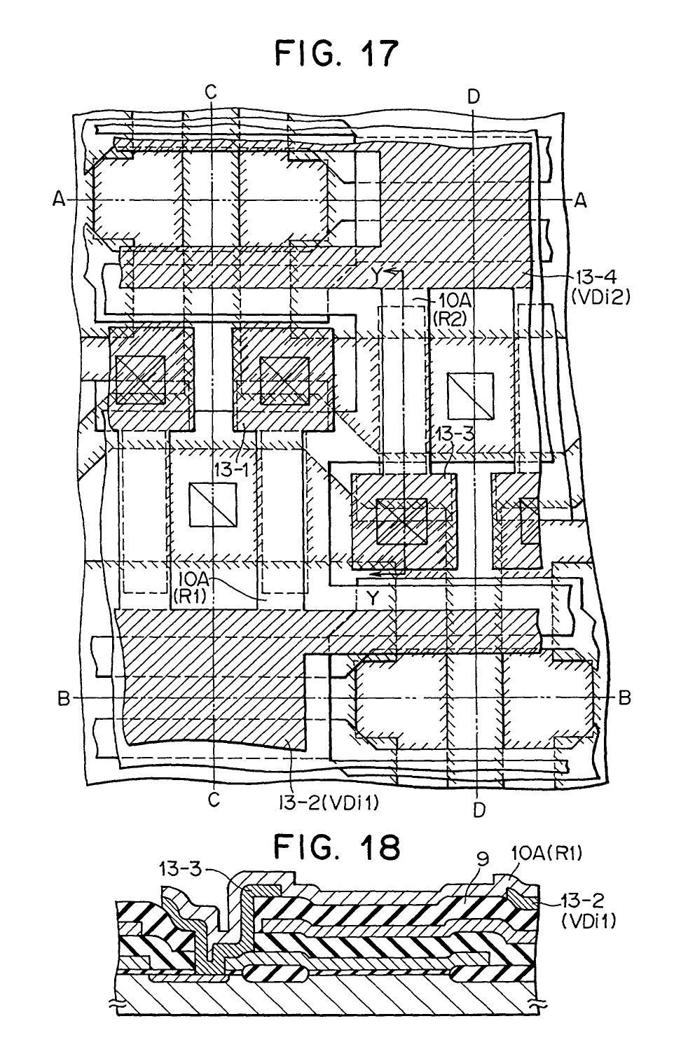

The next step will be illustrated with reference to FIG. 17 and FIG. 18 which is a sectional view along the line Y-Y in FIG. 17. As shown in FIGS. 17 and 18, patterning of the SIPOS film 10A is carried out to form a first high resistance film 10A (R1) connected to the first junction region 13-1 and the first power source wiring layer 13-2 (VDi1) and a second high resistance film 10A (R2) connected to the second junction region 13-3 and the second power source wiring layer 13-4 (VDi2). Incidentally, the first high resistance film 10A (R1) and the second high resistance film 10A (R2) may cover the entire surfaces of the first power source wiring layer 13-2 (VDi1) and second power source wiring layer 13-4 (VDi2) respectively as shown in the figure, though these films may cover a part of the surfaces.

Then, as shown in FIGS. 13 and 14, a layer insulating film 11 is deposited to form bit contact holes C3-1 and C3-2 extending to n+-type diffusion layers 6-3 and 6-4 respectively, followed by forming bit conductors 12 (Di) and 12 (NDi).

The silicon grain of the SIPOS film may be amorphous or polysilicon depending on the subsequently expected heat treatment and its condition. Incidentally, the growing conditions, necessity and conditions of doping, and necessity and conditions of heat treatment may be determined corresponding to the design values for the loading resistors R1 and R2.

Because the junction regions 13-1 to 13-4 are formed of polysilicon films (the layer resistance can be reduced to tens of Ω/□) doped with phosphorus, a reduction in the resistance of the junctions of the high resistance element can be achieved in a stable manner. The doping may be carried out by the following methods: Specifically, a film may be formed while introducing an impurity or an impurity may be diffused after a film is formed. Since the use of ion implantation is unnecessary, the present invention differs from the prior art technologies in no chances of production of high resistance sections (a high resistance section 10-C in FIG. 9) and the consistency with the formations of a source/drain region which is shallow in joint depth. Furthermore, in order to form a high resistance element, a resist film forming step is carried out twice, specifically, in the stages of patterning of the polysilicon film and patterning of the SIPOS film. The prior art technologies, in turn, require to perform a resist film forming step twice, specifically, in the stage of patterning of a SIPOS film and of in the stage of ion implantation. There is no difference in the numbers of times of the resist film forming step in the present invention and the prior art technologies.

Though the foregoing is for explanations about the case of using, as the high resistance film, a SIPOS film having potential to increase a layer resistance to several to tens of TΩ/□, the present invention is not limited to a SIPOS but is adaptable to general high resistance films used in semiconductor devices.

What is claimed is:

1. A semiconductor device mounted with a high resistance element comprising:
a semiconductor substrate;
a pair of junction regions formed of a low resistance polysilicon film, the pair of junction regions being formed on a semiconductor substrate; and
a high resistance film which is in contact with the pair of junction regions.

2. A semiconductor device according to claim 1, wherein said high resistance film is a SIPOS film formed of a silicon film containing oxygen.

3. A semiconductor device comprising:
a first inverter provided with a first loading resistor consisting of a first insulating gate transistor and a first high resistance element;
a second inverter provided with a second loading resistor consisting of a second insulating gate transistor and a second high resistance element; and
a memory cell containing a flip-flop circuit which applies output signals from said first and second inverters to gate electrodes of said second and first insulating gate transistors respectively, wherein:
said first high resistance element consists of a first low resistance polysilicon film connected with a drain region of said first insulating gate transistor, a second low resistance polysilicon film to which a prescribed voltage is applied, and a first high resistance film which is in contact with said first low resistance polysilicon film and said second low resistance polysilicon film; and
said second high resistance element consists of a third low resistance polysilicon film connected with a drain region of said second insulating gate transistor, a fourth low resistance polysilicon film to which a prescribed voltage is applied, and a second high resistance film which is in contact with said third low resistance polysilicon film and said fourth low resistance polysilicon film.

4. A semiconductor device according to claim 3, wherein said first and second high resistance films are a SIPOS film formed of a polysilicon film containing oxygen.

5. A process for manufacturing a semiconductor device comprising the steps of:
forming a low resistance silicon film doped with an impurity on a semiconductor substrate;
patterning said low resistance silicon film to form a pair of junction regions;
forming a high resistance film which is in contact with said pair of junction regions; and
patterning said high resistance film to form a high resistance element.

6. A process for manufacturing a semiconductor device according to claim 5, wherein said step of forming the high resistance film is a step of forming a SIPOS film composed of a silicon film containing oxygen by a CVD method in an atmosphere involving SiH4 gas and N2O gas.

7. A process for manufacturing a semiconductor device comprising the steps of:
forming an element isolation region in the surface of a first electro-conductive region disposed in the surface section of a semiconductor substrate to form partitioned first and second active regions;
forming a gate insulating film on the first and second active regions;
forming a polysilicon film doped with a second electro-conductive-type impurity;
patterning said polysilicon film to form a first gate electrode crossing over said first active region and extending to the periphery of said second active region; a second gate electrode crossing over said second active region and extending to the periphery of said first active region; a third gate electrode crossing over said first active region whose periphery is selectively coated with said second gate electrode and serving as a first word conductor; and a fourth gate electrode crossing over said second active region whose periphery is selectively coated with said first gate electrode and serving as a second word conductor;
introducing an impurity into said first and second active regions using, as a mask, said first gate electrode to said fourth gate electrode and said element isolation region to form a plurality of second electro-conductive-type regions thereby creating a first insulating gate transistor to a fourth insulating gate transistor which are provided with said first gate electrode to said fourth gate electrode respectively;
depositing a first layer insulating film to form a first earth contact hole and a second earth contact hole on a source region of said first insulating gate transistor as said second electro-conductive-type region which is not sandwiched between said first gate electrode and said third gate electrode and on a source region of said second insulating gate transistor as said second electro-conductive-type region which is not sandwiched between said second gate electrode and said fourth gate electrode respectively;
depositing an electro-conductive film, followed by patterning to form an earth wiring layer;
depositing a second layer insulating film to form a first common contact hole and a second common contact hole, said first common contact hole exposing a drain region of said first insulating gate transistor as said second electro-conductive-type region which is sandwiched between said first and third gate electrodes and said second gate electrode adjacent to said drain region, and said second common contact hole exposing a drain region of said second insulating gate transistor as said second electro-conductive-type region which is sandwiched between said second and fourth gate electrodes and said first gate electrode adjacent to said drain region;
forming a polysilicon film doped with a second electro-conductive-type impurity, followed by patterning to form a first junction region and a second junction region and a first power source wiring layer and a second power source wiring layer for filling up said first and second contact holes; and successively forming a first high resistance film connected with said first junction region and said first power source wiring layer and a second high resistance film connected with said second junction region and said second power source wiring layer; and
depositing a third layer insulating film to form a first bit contact hole and a second bit contact hole for exposing said second electro-conductive-type region formed sandwiching said third gate electrode between said drain region of said first insulating gate transistor and said second electro-conductive-type region formed sandwiching said fourth gate electrode between said drain region of said second insulating gate transistor; and successively forming a first bit wiring layer and a second bit wiring layer for filling up said first and second bit contact holes respectively to form a memory cell.

8. A process for manufacturing a semiconductor device according to claim 7, wherein said step of forming said first high resistance film and said second high resistance film is the steps of forming a SIPOS film composed of a silicon film containing oxygen by a CVD method in an atmosphere involving SiH₄ gas and N₂O gas and patterning them.
